(19) United States
(12) Patent Application Publication
(10) Pub. No.: US 2026/0090482 A1
(43) Pub. Date: Mar. 26, 2026

(54) POWER MODULE PACKAGE

(71) Applicant: SEMICONDUCTOR COMPONENTS INDUSTRIES, LLC, Scottsdale, AZ (US)

(72) Inventors: Hangil SHIN, Incheon (KR); Jihwan KIM, Seoul (KR); Taekyun KIM, Bucheon (KR); Seungwon IM, Bucheon (KR)

(73) Assignee: SEMICONDUCTOR COMPONENTS INDUSTRIES, LLC, Scottsdale, AZ (US)

(21) Appl. No.: 18/896,813

(22) Filed: Sep. 25, 2024

(51) Int. Cl. H01L 23/498; H01L 21/48; H01L 23/00; H01L 23/10; H01L 23/13; H01L 23/29; H01L 25/065; H01L 29/16; H01L 29/20; H01R 12/58

(52) U.S. Cl. CPC H10W 90/701; H10W 70/093; H10W 70/68; H10W 70/685; H10W 76/60; H01R 12/585; H10D 62/8325; H10D 62/8503; H10W 72/884; H10W 74/47; H10W 90/00; H10W 90/734; H10W 90/754

(57) ABSTRACT

An electronic power module is disclosed that forms external electrical connections without the use of a lead frame. Instead, various types of external connectors can be used, such as a press-fit pin assembly and an integrated connection post and power tap. Different methods of securing the external connectors to a multilayer substrate are also disclosed.

### TECHNICAL FIELD

This description relates to assembling and packaging semiconductor device modules, semiconductor device assemblies, and semiconductor devices. More specifically, this description relates to electrical connectors in a high power semiconductor device module.

### SUMMARY

In some aspects, the techniques described herein relate to a power module, including: a substrate including a first conductive layer, a second conductive layer, and an insulating layer disposed between the first conductive layer and the second conductive layer; a connection post coupled to the first conductive layer; a conductive sheath coupled to the first conductive layer, the conductive sheath configured to receive an external connector; a die coupled to the first conductive layer; and a non-conducting material encapsulating the die, at least a portion of the connection post, and the conductive sheath.

In some aspects, the techniques described herein relate to a power module, further including a press-fit pin inserted vertically into the conductive sheath.

In some aspects, the techniques described herein relate to a power module, wherein the connection post, the conductive sheath, and the press-fit pin include copper.

In some aspects, the techniques described herein relate to a power module, wherein the conductive sheath is a hollow metal via.

In some aspects, the techniques described herein relate to a power module, wherein the connection post has a shape of a cylinder, a square pillar, a round pillar, or a hybrid pillar.

In some aspects, the techniques described herein relate to a power module, wherein the connection post and a press-fit pin form external connections to the die.

In some aspects, the techniques described herein relate to a power module, wherein the connection post is formed as a pillar that includes a cylinder coupled to a base.

In some aspects, the techniques described herein relate to a power module, wherein the cylinder and the base have cross-sections of different shapes.

In some aspects, the techniques described herein relate to a power module, further including a power tap disposed on the connection post.

In some aspects, the techniques described herein relate to a method of forming a power module, the method including: adhering a multilayer substrate to a carrier, the multilayer substrate including a first conductive layer, a second conductive layer, and an insulating layer; disposing an external connector in a first conductive layer of the multilayer substrate; attaching a die to the first conductive layer; encapsulating the die and the external connector; detaching the carrier from the multilayer substrate; and singulating the multilayer substrate.

In some aspects, the techniques described herein relate to a method, wherein disposing the external connector in the first conductive layer includes forming a recess in the first conductive layer and inserting the external connector into the recess.

In some aspects, the techniques described herein relate to a method, wherein disposing the external connector in the first conductive layer includes disposing a connection post in the first conductive layer.

In some aspects, the techniques described herein relate to a method, further including forming a power tap on the connection post.

In some aspects, the techniques described herein relate to a method, wherein disposing the external connector in the first conductive layer includes disposing a conductive sheath in the first conductive layer.

In some aspects, the techniques described herein relate to a method, further including inserting a press-fit pin into the conductive sheath to couple the press-fit pin to the first conductive layer.

In some aspects, the techniques described herein relate to a method, wherein encapsulating the die and the external connector includes injection molding and grinding an encapsulant.

In some aspects, the techniques described herein relate to a package for an embedded semiconductor die, the package including: a multilayer substrate supporting the embedded semiconductor die; an encapsulant surrounding the embedded semiconductor die; and a plurality of electrical connections coupling the embedded semiconductor die to the multilayer substrate, the plurality of electrical connections including: a conductive material coupled to a surface layer of the multilayer substrate; a connection post embedded in the surface layer; and a press-fit pin assembly embedded in the surface layer, the press-fit pin assembly including a conductive sheath.

In some aspects, the techniques described herein relate to a package, wherein the multilayer substrate is a direct bond copper substrate including a dielectric layer between two copper layers.

In some aspects, the techniques described herein relate to a package, wherein the press-fit pin assembly includes a press-fit pin, a flat portion, and flexible metal blades.

In some aspects, the techniques described herein relate to a package, wherein the connection post is T-shaped.

In some aspects, the techniques described herein relate to a package, wherein the connection post is a solid metal via.

In some aspects, the techniques described herein relate to a package, wherein the conductive sheath is a hollow metal via.

In some aspects, the techniques described herein relate to a package, wherein the encapsulant includes a non-electrically conducting material.

In some aspects, the techniques described herein relate to a package, wherein the encapsulant includes an organic material.

In some aspects, the techniques described herein relate to a package, wherein the encapsulant includes multiple layers.

In some aspects, the techniques described herein relate to a package, further including one or more additional semiconductor dies.

In some aspects, the techniques described herein relate to a package, wherein the embedded semiconductor die includes at least one of silicon, silicon carbide, gallium nitride, or another compound semiconductor material, and combinations thereof.

### BRIEF DESCRIPTION OF THE DRAWINGS

FIG. 1 is a cross-sectional view of a power module, according to some implementations of the present disclosure.

FIGS. 2A-2F illustrate various options for securing an external connector to a multilayer substrate, according to some implementations of the present disclosure.

FIGS. 3A-3G illustrate various structures for use as external connectors in a power module, according to some implementations of the present disclosure.

FIGS. 4A-4E illustrate various pillar designs for use as external connectors in a power module, according to some implementations of the present disclosure.

FIG. 5 is a flow diagram of a method for fabricating a power module, according to some implementations of the present disclosure.

FIGS. 6A, 6B, and 7-10 illustrate steps in the method shown in FIG. 5, according to some implementations of the present disclosure.

FIG. 11 is a flow diagram of a method for fabricating a power module, according to some implementations of the present disclosure.

FIGS. 12-16 illustrate steps in the method shown in FIG. 11, according to some implementations of the present disclosure.

FIG. 17A is a perspective view of an embedded die, according to some implementations of the present disclosure.

FIGS. 17B and 17C are cross-sectional views of embedded dies, according to some implementations of the present disclosure.

Aspects of the present disclosure are best understood from the following detailed description when read with the accompanying figures. It is noted that, in accordance with common practice in the industry, various features are not necessarily drawn to scale. Dimensions of the various features may be arbitrarily increased or reduced for clarity of discussion. In the drawings, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings but are provided for context between related views. Also, not all like elements in the drawings are specifically referenced with a reference symbol when multiple instances of an element are illustrated.

### DETAILED DESCRIPTION

As described herein, semiconductor device assemblies, e.g., chip assemblies that include power semiconductor devices, can be implemented using multiple semiconductor dies, substrates (e.g., die attach pads (DAPs)), electrical interconnections, embedded die structures, and a molding compound. The power transistors described herein can include, for example, insulated-gate bipolar transistors (IGBTs), power metal-oxide-semiconductor field effect transistors (MOSFETs), and so forth. Electrical interconnections within a high-power semiconductor device module can include, for example, bond wires, conductive spacers, metal and insulating built up layers, and conductive clips. A lead frame may also be used to provide external electrical connections to the high-power semiconductor device module. A non-conducting material, for example, polymer molding compound, can serve as an encapsulant to protect components of the device assembly. Some of the high-power chip assemblies described herein can operate at voltages in a range of about 200 V to about 800 V. Such high-power chip assemblies, encapsulated as embedded semiconductor device modules, can be used in various applications, including electric vehicles (EVs), hybrid electric vehicles (HEVs), and industrial applications.

Within the power modules described herein, it is important to provide strong and reliable electrical connections to electronic devices that operate at high voltages and carry high currents, to safely deliver electric power to the devices, and to ensure accurate signal transmission. It is also important, within these power modules, to dissipate heat generated within power semiconductor devices to limit possible adverse effects of overheating such as dimensional variations, variable operating characteristics, and differential thermal expansion. Overheating can compromise reliability of the devices and/or can also waste power, thereby increasing operating costs. Ineffective cooling of semiconductor devices may impose limitations on the design of power chip assemblies by constraining permissible power density, circuit density, or system speed. When heat is dissipated from a source (e.g., a power module) to a sink (e.g., a heat sink) by conduction, successful heat transfer can depend on the direct contact area between the source and the heat sink.

In some power modules, chip assemblies are supported by a multilevel substrate, e.g., a direct-bonded metal (DBM) structure (which can be a direct-bonded copper (DBC) substrate). The DBM can be used, in part, to provide a current path for external devices to access the chip assemblies, and to facilitate cooling of high power semiconductor devices. The DBM structure can include a first conductive layer, a second conductive layer, and a non-conductive layer (e.g., a dielectric layer, a ceramic layer) made of an insulating material disposed between the first conductive layer and the second conductive layer. The first conductive layer (and/or the second conductive layer) can include, or can define, one or more electrical traces and/or connections. The second conductive layer (and/or the first conductive layer) can be, or can function as, a heat sink. In some implementations, multiple DBMs (e.g., two DBMs) can be used for double-sided cooling, or for cooling multiple arrays of high power chips. In some implementations, the second conductive layer can be coupled to a heat sink for single-sided cooling.

This disclosure relates to implementations of external connectors, that is, connectors that couple the first conductive layer of the DBM to external devices. Such external connectors can be used instead of a lead frame. In some implementations, a lead frame is a conductive layer made from a thin rolled sheet of metal, e.g., copper, that is stamped with a pattern of connectors such as die attach pads (DAPs) and metal traces. With the use of external connectors, e.g., connection posts and press-fit pin assemblies, reliance on a lead frame can be avoided, thus saving costs, reducing the footprint of the power module, reducing stray inductance, and simplifying the manufacturing process.

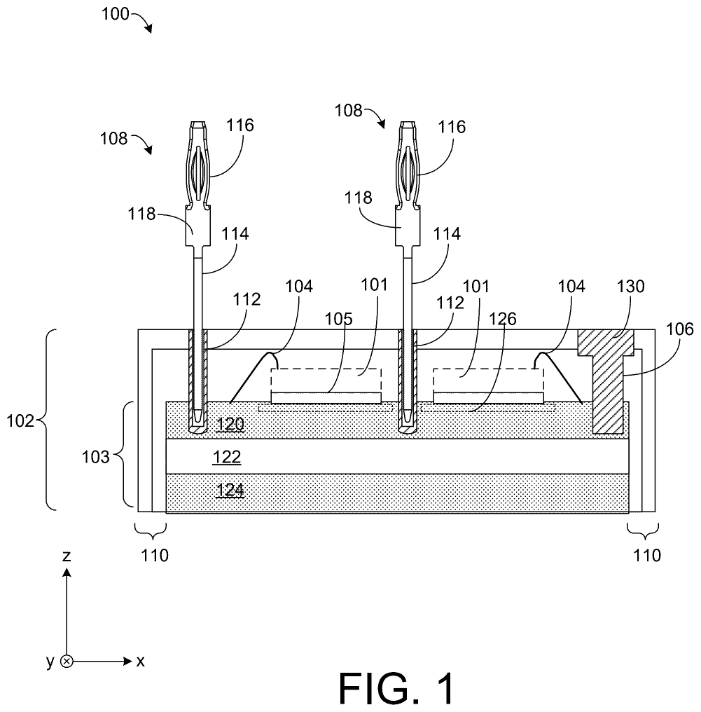

FIG. 1 is a cross-sectional view of a power module 100, in accordance with some implementations of the present disclosure. The power module is implemented with external connectors instead of a lead frame. External connectors in the form of connection posts and press-fit pin assemblies are shown in FIG. 1 and described below. The use of such external connectors provides an alternative to a copper lead frame, at a reduced cost, and with a smaller footprint. By eliminating the use of a lead frame, which is formed as a separate layer, the manufacturing process is simplified.

The power module 100 includes a semiconductor die 101 and a package 102 for the semiconductor die 101. The semiconductor die 101, e.g., a chip assembly, can be an integrated circuit die and/or a die that includes one or more discrete high power electronic components. In some implementations, the semiconductor die 101 can be an embedded semiconductor die. The semiconductor die 101 is shown as a dashed-line box in FIG. 1. All of the other items shown in FIG. 1 can be considered as elements of the package 102.

In some implementations, the package 102 can include a multilayer substrate 103, a conductive material 104, an adhesive 105, a connection post 106 (one shown), a press-fit pin assembly 108 (two shown), and an encapsulant 110. In some implementations, each press-fit pin assembly 108 can include a press-fit pin 114. In some implementations, each press-fit pin assembly 108 can further include flexible metal blades 116 and/or a flat portion 118.

In some implementations, the multilayer substrate 103 can be a direct-bonded metal (DBM) structure. In some implementations, the multilayer substrate 103 can be a direct bond copper (DBC) type structure, a direct plating copper (DPC) type structure, or a direct bond aluminum (DBA) type structure. The semiconductor die 101, during high power operation, may generate heat and may cause heat accumulation within the power module 100. The multilayer substrate 103 may be a heat spreader that provides single-sided cooling for the semiconductor die 101. In some implementations, the multilayer substrate 103 is designed as a three-layer DBM structure that includes a non-conductive layer 122 disposed between, e.g., sandwiched between a first conductive layer 120 and a second conductive layer 124. In some implementations, the non-conductive layer 122 serves as a thermal mass disposed between the two outer metal layers to draw in and absorb heat. The non-conductive layer 122 may also provide electrical insulation between the first conductive layer 120 and the second conductive layer 124 of the multilayer substrate 103.

In some implementations, the first conductive layer 120 and/or the second conductive layer 124 can be, or can include, a metal layer (e.g., a copper layer, a copper alloy layer) that is formed on (e.g., bonded to, sputtered on, diffused onto to, heat-formed on) the non-conductive layer 122. The first conductive layer 120 can be coupled to a first side of the non-conductive layer 122, and the second conductive layer 124 can be coupled to a second side of the non-conductive layer 122.

In some implementations, the non-conductive layer 122 can include a ceramic material, e.g., silicon nitride (Si₃N₄) or aluminum oxide (Al₂O₃), Si₃N₄ being a significantly more expensive ceramic material than Al₂O₃. The first conductive layer 120 or the second conductive layer 124 can be referred to as an upper conductive layer, e.g., a top layer, or as a lower conductive layer, e.g., a bottom layer, depending on the orientation of the device.

The first conductive layer 120 can be, or can include, a metal redistribution layer (RDL) pattern on which to mount (or couple) the semiconductor die 101 using a die attach (DA) 126. The DA 126 can be integral to, or attached to, the first conductive layer 120 of the multilayer substrate 103. The DA 126 is shown as a dotted line box region under the semiconductor die 101. The DA 126 can be solder and/or metal sintering, including silver (Ag) sintering. One or more semiconductor dies 101, also called chip assemblies (two shown), can be in contact with the DA 126. In some implementations, the non-conductive layer 122 and/or the second conductive layer 124 of the multilayer substrate 103 can have a larger footprint than the DA 126.

In some implementations, the semiconductor die 101 can be mounted on (e.g., attached to, coupled to, adhered to) the multilayer substrate 103 by the DA 126 using solder or a sintering layer e.g., a conductive epoxy, a silver (Ag) or copper (Cu) sintering material, and/or a adhesive., e.g., a bonding agent, an epoxy, a glue, a tape such as a polyimide tape, or other type of conductive adhesive. In some implementations that include multiple semiconductor dies 101, first and second semiconductor dies 101 can be coupled to the DA 126 by two different bonding agents. For example, in some implementations, a first semiconductor die 101 can be attached to the metal pattern of the multilayer substrate 103 by sintering, while a second semiconductor die 101 is attached by the DA 126 to the metal pattern of the multilayer substrate 103 using conductive polyimide tape.

In some implementations, the semiconductor die 101 can include for example, a controller and/or an insulated gate bipolar transistor (IGBT). In some implementations that include multiple semiconductor dies 101, such dies can include an IGBT, and a controller configured to control the IGBT. The controller can also serve as a protection device for the IGBT. For example, the controller can provide temperature protection and/or over-voltage protection for the IGBT. The controller can also limit the amount of current delivered to the IGBT. In some implementations, the controller can be configured to monitor the IGBT. In some implementations, other types of semiconductor dies, e.g., silicon MOSFETs, silicon carbide (SiC) MOSFETs, diodes, and so forth, can be used. In some implementations, a SiC MOSFET can be substituted for the IGBT. In some implementations, fast recovery diodes (FRDs) may be used in conjunction with power transistors.

The semiconductor die 101 can be fabricated on various types of semiconductor substrates, e.g., semiconductor wafers, for example, silicon (Si), silicon carbide (SiC), gallium (Ga), or compound semiconductor materials such as gallium nitride (GaN), aluminum gallium nitride (AlGaN), gallium arsenide (GaAs), aluminum gallium arsenide (AlGaAs), or indium phosphide (InP). In some implementations, the semiconductor die 101 can be fabricated on glass or sapphire substrates. In general, any type of semiconductor die 101 can be fabricated on any type of substrate.

One or more of the semiconductor dies 101 can further include layers made of silicon, gallium, or compound semiconductor materials including silicon carbide (SiC), gallium nitride (GaN), aluminum gallium nitride (AlGaN), gallium arsenide (GaAs), aluminum gallium arsenide (AlGaAs), indium phosphide (InP), gallium phosphide (GaP), aluminum antimonide, cadmium telluride (CdTe), and so on. For example, a first semiconductor die (e.g., one of the semiconductor die 101) can be made of a semiconductor material including SiC and a second semiconductor die (e.g., another of the semiconductor die 101) can be made of a semiconductor material including silicon (Si).

In some implementations, the compound semiconductor materials used in the substrate or in layers subsequently deposited over the substrate, combine elements, e.g., two or three elements, from groups III and V of the periodic table (e.g., gallium and arsenic, or aluminum, gallium, and arsenic). In some implementations, the compound semiconductor materials used in the substrate or in layers formed on the substrate combine elements from groups II and VI of the periodic table, (e.g., cadmium and tellurium). In some implementations, the compound semiconductor materials used in the substrate or in layers formed on the substrate combine different elements from group IV of the periodic table (e.g., silicon and carbon).

Advantages of compound semiconductor materials over silicon can include, for example, optical properties that provide highly efficient light transmission, high electron mobility that permits fast transistor switching speeds, and piezoelectric properties. In addition, compound semiconductors have the ability to generate signals with high frequencies, and to operate at high temperatures with a high breakdown voltage. Devices that can operate at high temperatures without suffering breakdown are desirable for high power applications such as automotive and industrial applications, and radio frequency (RF) modules. In some implementations, different semiconductor dies 101 can be fabricated on different substrates in a hybrid configuration. For example, an IGBT can be fabricated on a SiC substrate, while a controller can be fabricated on a silicon substrate. In some implementations as described herein, multiple semiconductor dies 101 can be fabricated on the same substrate, e.g., on a SiC substrate, suitable for high power applications.

In some implementations, the encapsulant 110 can include a non-electrically conducting material, e.g., a molding material or molding compound, or an organic material. For example, the encapsulant 110 can include a molding material such as a polymer material e.g., an epoxy molding compound (EMC) that serves to seal and protect the various components of the power module 100, e.g., by surrounding, for example, the semiconductor die 101. In some implementations, the encapsulant 110 can include multiple layers (two layers shown in FIG. 1). Encapsulation can be accomplished by, for example, a process of injection molding or a process of transfer molding. In some implementations, the encapsulant 110 can expose the multilayer substrate 103 through openings in the encapsulant 110 (not shown). In some implementations, the multilayer substrate 103 can be disposed in an opening in the encapsulant 110 so that the second conductive layer 124 is exposed on the bottom of the power module 100. In some implementations, the second conductive layer 124 can be placed in contact with a heat sink so as to dissipate heat produced by the power module 100.

In some implementations, the press-fit pin assembly 108 is embedded in the first conductive layer 120 such that a first end of the press-fit pin assembly 108 extends vertically (or substantially vertically) into a center portion of the first conductive layer 120 of the multilayer substrate 103. A second end of the press-fit pin assembly 108 extends outward from the surface of the encapsulant 110.

As shown in FIG. 1, the conductive sheath 112 forms (e.g., defines) a lining around the press-fit pin 114, within the encapsulant 110 and the first conductive layer 120. In some implementations, the conductive sheath 112 has a tubular, e.g., hollow shape, configured to receive the press-fit pin following insertion of the conductive sheath into a recess in the first conductive layer 120. The conductive sheath 112 thus can serve as a holder, supporting the press-fit pin 114 as well as providing electrical contact between the press-fit pin 114 and the first conductive layer 120. In some implementations, the conductive sheath 112 and/or the press-fit pin 114 can be made of a high conductivity metal such as copper or aluminum so that the conductive sheath 112 forms a hollow metal via.

In some implementations, the first end of the, e.g., tapered to a point, along its length in the-z-direction. In some implementations, the tapered portion of the press-fit pin 114 can be below the surface of the first conductive layer 120. The tapered portion of the press-fit pin 114 can be at the tip so that most of the surface area of the press-fit pin 114 contacts the conductive sheath 112, forming a tight seal.

When pinched together, the flexible metal blades 116 at the second end of the press-fit pin assembly 108 can provide a grip to assist in inserting the press-fit pin 114 into the conductive sheath 112, so that the press-fit pin 114 fits tightly in the conductive sheath 112 and extends almost to the bottom of the conductive sheath 112. In some implementations, the flat portion 118 can provide leverage to facilitate insertion of the press-fit pin 114 into the conductive sheath 112 by allowing a user to rotate the press-fit pin 114, e.g., around the z-axis, within the conductive sheath 112 while applying downward pressure, e.g., in the-z direction, to the press-fit pin 114. In some implementations, a press-fit pin assembly 108 can be installed next to each semiconductor die 101.

In some implementations, the connection post 106 is embedded in the first conductive layer 120 such that a first end of the connection post 106 extends vertically into the first conductive layer 120 of the multilayer substrate 103 while a second end of the connection post 106 is flush or substantially flush with a top surface of the encapsulant 110. In some implementations, the encapsulant together with the second end of the connection post 106 define a planar surface. In some implementations, the connection post 106 is a solid metal via having a T-shaped profile, wherein a top portion of the connection post 106 can be wider in the x-direction than a lower portion that is embedded in the first conductive layer 120. The top portion of the T-shaped structure can serve as a power tap 130 that is accessible to outside connections, e.g., to a power source for energizing the semiconductor dies 101. The y-dimension, e.g., depth, of the connection post 106 can be sized, e.g., patterned, in accordance with power specifications of the power module 100. In some implementations, the connection post 106 can be installed at one end of the power module 100. The first conductive layer 120 can be patterned so that the connection post 106 may or may not be electrically coupled to one or more of the press-fit pin assemblies 108, depending on a circuit design.

In some implementations, the power module 100 can have a total area of about 25×35 mm². In some implementations, the multilayer substrate 103 has a total thickness in a range of about 0.5 mm to about 3.0 mm.

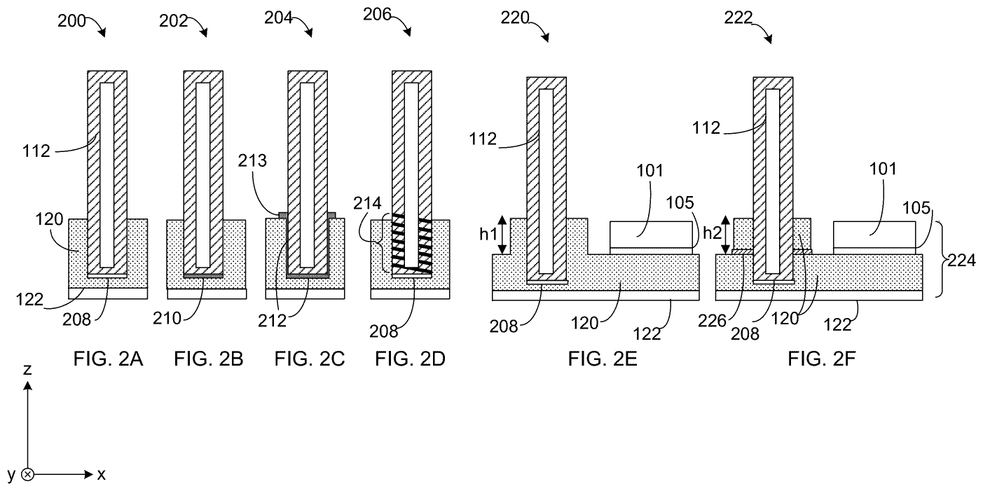

FIGS. 2A-2D illustrate structural variations of an external connector that features the conductive sheath 112, according to some implementations of the present disclosure. In particular, FIGS. 2A-2D illustrate different options for securing the conductive sheath 112 to the first conductive layer 120 of the multilayer substrate 103, for use in the power module 100 shown in FIG. 1.

With reference to FIG. 2A, in a first implementation, an external connector 200 can be formed by forming a recess in the first conductive layer 120 and then directly inserting the conductive sheath 112 into the recess. The recess can be formed in the first conductive layer 120 by etching, stamping, drilling, or similar methods. In some instances, the conductive sheath 112 may not be fully inserted so that a bottom portion of the recess e.g., a gap 208, remains after the conductive sheath 112 is in place, resulting in insufficient electrical contact between the bottom of the conductive sheath 112 and the first conductive layer 120.

With reference to FIG. 2B, in a second implementation, an external connector 202 can be formed by inserting the conductive sheath 112 into the recess in the first conductive layer 120 that further includes a bonding material 210 at the bottom of the recess. The bonding material 210 can include materials such as a solder, a silver sintering material, a copper sintering material, and/or other metal-to-metal type bonding materials. Use of the bonding material 210 fills the bottom of the recess, to ensure there is no gap, so that a strong electrical contact exists between the bottom of the conductive sheath 112 and the first conductive layer 120.

With reference to FIG. 2C, in a third implementation, an external connector 204 can be formed by inserting the conductive sheath 112 into a recess in the first conductive layer 120 and then securing the conductive sheath 112 to the first conductive layer 120 by welding.

The welding process can line the recess with a welding layer 212, e.g., a copper welding layer. In some implementations, the welding layer 212 can include a copper bead 213 at the surface of the first conductive layer 120. The welding layer 212 may have a higher conductivity than the bonding material, and may therefore decrease electrical resistance between the conductive sheath 112 and the first conductive layer 120 compared with the resistance of the second external connector 202.

With reference to FIG. 2D, in a fourth implementation, an external connector 206 can be formed by inserting the conductive sheath 112 into the recess in the first conductive layer 120 and securing the conductive sheath 112 to the first conductive layer 120 with screw threads 214 formed in the conductive sheath 112.

FIG. 2E illustrates a first way to increase the recess depth into the first conductive layer 120 of the multilayer substrate 103 for greater stability of the external connectors. As shown in FIG. 2E, in a fifth implementation, to support an external connector 220, the first conductive layer 120 can be partially etched to a depth h1, excluding the vicinity of the conductive sheath 112. An additional thickness h1 of the first conductive layer 120 around the base of the conductive sheath 112 can improve structural stability of the external connector 220 by supporting a greater depth of the conductive sheath 112. The semiconductor die 101 and the adhesive 105 are shown in FIGS. 2E and 2F for context.

FIG. 2F illustrates a second way to increase the recess depth into the first conductive layer 120 of the multilayer substrate 103 for greater stability of the external connectors. As shown in FIG. 2F, in a sixth implementation, an external connector 222, a stacked metal substrate 224 can replace the first conductive layer 120. The stacked metal substrate 224 can include two thicknesses of the first conductive layer 120 separated by a thin layer 226, made of a different metal than the first conductive layer 120. Then the top two layers of the stacked metal substrate 224 can be etched to a depth h2 to form a support around the base of the conductive sheath 112. The additional thickness h2 of the stacked metal substrate 224 around the base of the conductive sheath 112 can improve structural stability of the external connector 220 by supporting a greater depth of the conductive sheath 112.

Multiple ones of the six variations of external connectors 200, 202, 204, 206, 220, and 222 can be used on the same substrate, and/or in the same power module 100. For example, one of the two press-fit pin assemblies 108 shown in FIG. 1 can be secured in the first conductive layer 120 using the external connector 202 while the other press-fit pin assembly 108 can be secured in the first conductive layer 120 using the external connector 206. In some implementations, both of the press-fit pin assemblies 108 can be secured in the first conductive layer 120 using the external connector 204. With masking, combinations of the six variations of external connectors described above can be present on the same substrate, and/or in the same power module 100.

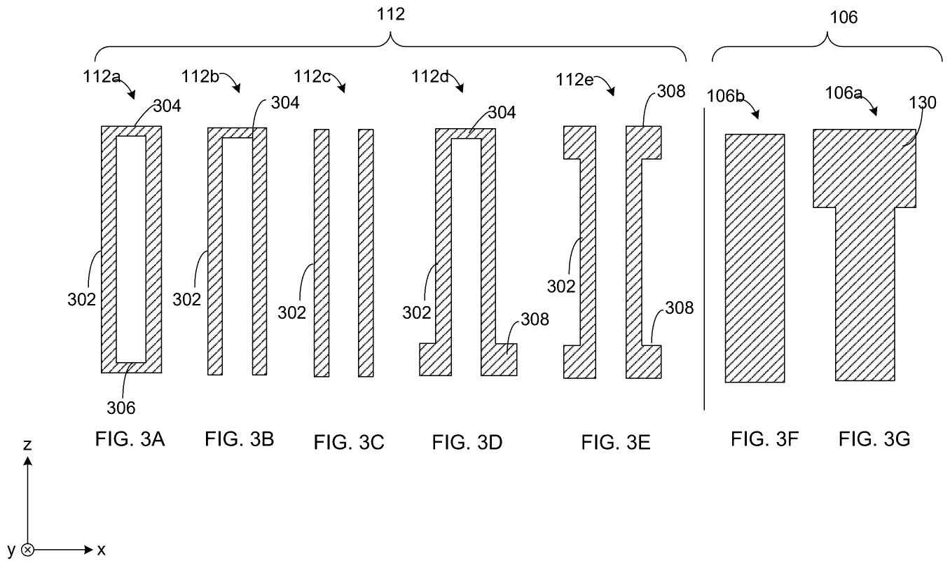

FIGS. 3A-3G illustrate various types of structures that can be used as the conductive sheath 112 (five shown, 112a-112e) and as the connection post 106 (two shown, 106a and 106b) in the power module 100, according to some implementations of the present disclosure. In addition to, or instead of, the conductive sheath 112a shown in FIG. 3A other external connectors can be used. FIGS. 3A-3G show cross-sectional cuts of the various structures, which may extend in the y-direction in a symmetric fashion.. In some implementations, the external connectors 112a-112e and 106a-106b can be made of a high conductivity material, e.g., a metal such as copper, or a copper alloy such as aluminum copper (AlCu).

With reference to FIG. 3B, in a second implementation, a U-shaped conductive sheath 112b that is open at the bottom can be substituted for the closed rectangular conductive sheath 112a shown in FIG. 3A. Otherwise, like the closed rectangular conductive sheath 112a, the U-shaped conductive sheath 112b may have sidewalls 302 and a top wall 304 of substantially uniform width, or the top wall 304 have a different width than the sidewalls 302.

With reference to FIG. 3C, in a third implementation, a tubular conductive sheath 112c, which is open at the top as well as open at the bottom, can be substituted for the closed rectangular conductive sheath 112a shown in FIG. 3A. Otherwise, similar to the closed rectangular conductive sheath 112a, the tubular conductive sheath 112c may have sidewalls 302 of substantially uniform width, which may extend into the y-direction.

With reference to FIG. 3D in a fourth implementation, an enhanced U-shaped conductive sheath 112d. which is open at the bottom, can be substituted for the U-shaped conductive sheath 112b shown in FIG. 3B. Otherwise, similar to the U-shaped conductive sheath 112a, the enhanced U-shaped conductive sheath 112d may have sidewalls 302 and a top wall 304 of substantially uniform width, which may extend into the y-direction. However, the enhanced U-shaped conductive sheath 112d features the addition of pedestals 308 at the bottoms of the sidewalls 302. The pedestals 308 can extend along the y-direction and may serve to anchor the sidewalls 302, In some implementations, the pedestals 308 may improve electrical conductivity to the first conductive layer.

With reference to FIG. 3E in a fifth implementation, an enhanced tubular conductive sheath 112e. which is open at the top and also open at the bottom, can be substituted for the tubular conductive sheath 112c shown in FIG. 3C. Otherwise, similar to the tubular conductive sheath 112c, the enhanced tubular conductive sheath 112e may have sidewalls 302 of substantially uniform width, which may extend into the y-direction. However, the enhanced tubular conductive sheath 112e features the addition of pedestals 308 at the bottoms and tops of the of the sidewalls 302. The pedestals 308 can extend along the y-direction and may serve to anchor the sidewalls 302, In some implementations, the pedestals 308 may improve electrical conductivity to the first conductive layer.

With reference to FIG. 3F, in a sixth implementation, a straight metal connection post 106b, e.g., a solid metal via having straight sidewalls, can be substituted for the T-shaped connection post 106a shown in FIG. 1 and reproduced in FIG. 3G. The straight metal connection post 106b does not include the power tap 130, but may still serve as a power connection for the semiconductor die 101.

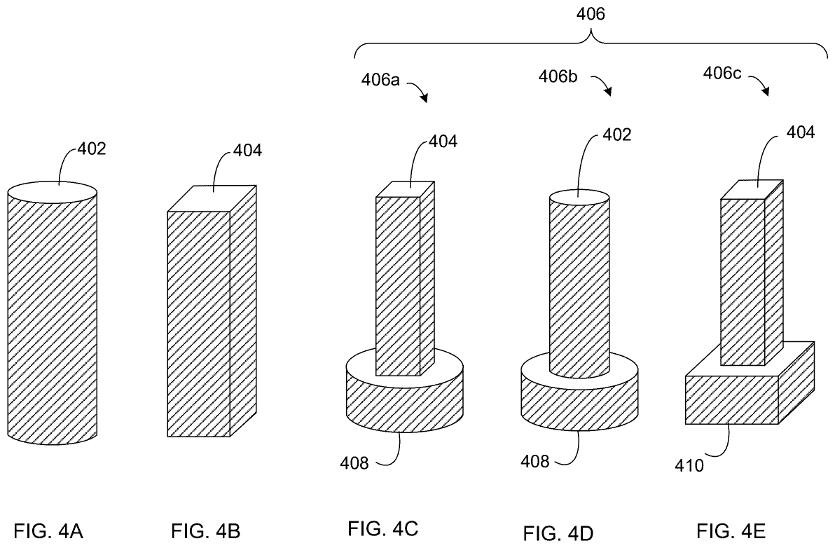

FIGS. 4A-4E illustrate various types of connection post structures that can be used as external connectors in the power module 100 shown in FIG. 1, according to some implementations of the present disclosure. In some implementations, connection posts 106 in the power module 100 can include pillars. The pillars can be made of high conductivity material, e.g., a metal such as copper, or a copper alloy such as aluminum copper (AlCu). The types of pillars can include shapes having different cross-sections, for example, a round cylinder 402, a square cylinder 404, and hybrid pillars 406 (three shown, 406a, 406b, and 406c. In some implementations, the hybrid pillars 406 include a cylindrical portion, e.g., the round cylinder 402 or the square cylinder 404, attached to a base. For example, the square cylinder 404 can be attached to a round base 408 to form the hybrid pillar 406a, as shown in FIG. 4C; or the round cylinder 402 can be attached to the round base 408 to form the hybrid pillar 406b, as shown in FIG. 4D; or the square cylindrical 404 can be attached to the square base 410, to form the hybrid pillar 406c, as shown in FIG. 4E.

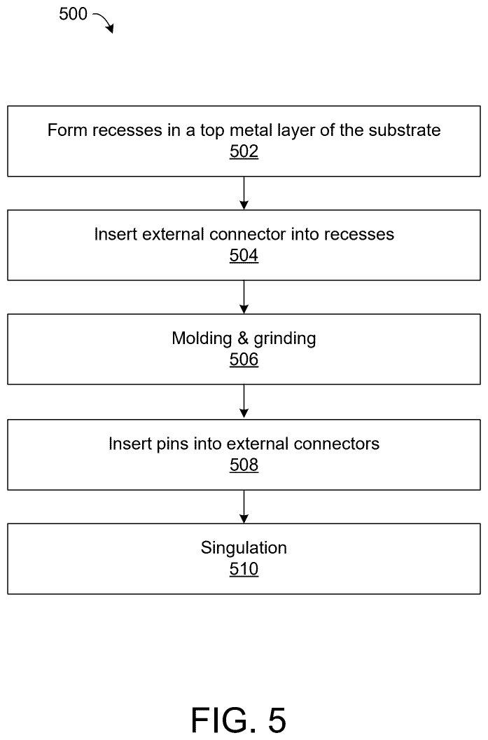

FIG. 5 is a flow chart illustrating a method 500 for fabricating the power module 100, according to some implementations of the present disclosure. Operations of method 500 can be performed in a different order, or not performed, depending on specific applications. It is noted that method 500 may not produce a complete power module 100. Accordingly, it is understood that additional processes can be provided before, during, or after method 500, and that some of these additional processes may be briefly described herein.

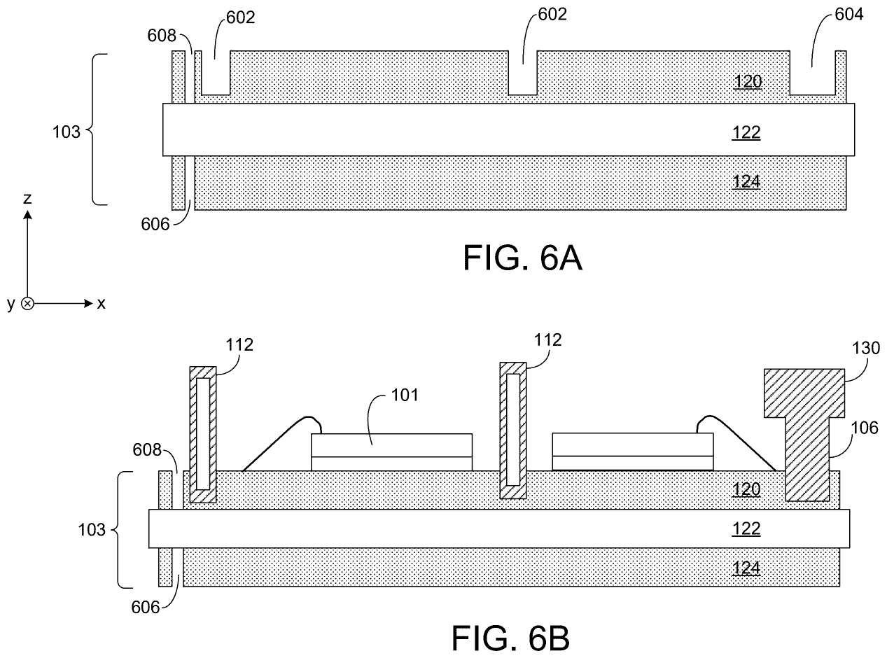

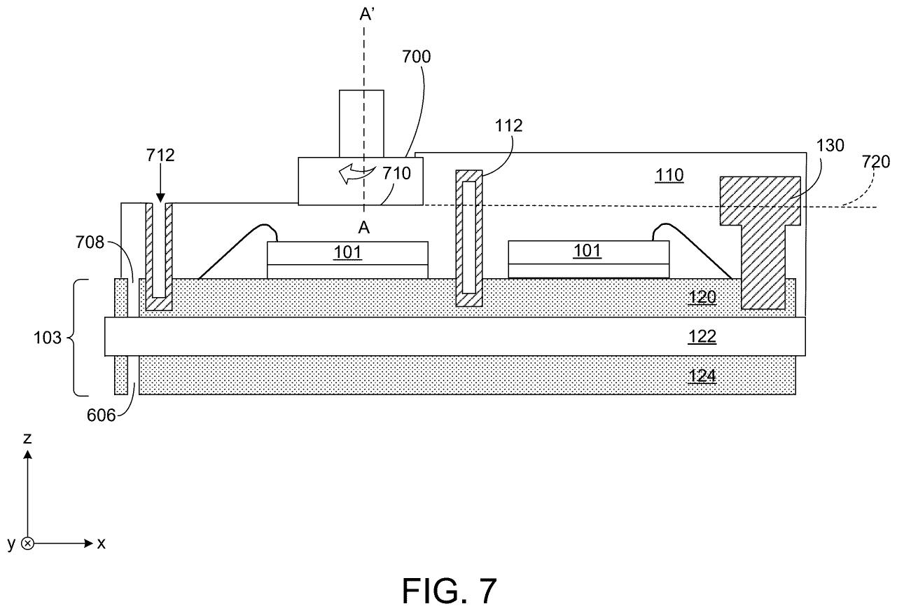

Operations 502-510 can be carried out to form power module 100 according to some implementations as described above, with reference to FIG. 6A, FIG. 6B, and FIGS. 7-10.

At 502, the method 500 includes forming narrow recesses 602 and a wide recess 604 in a top metal layer, e.g., the first conductive layer 120 of the multilayer substrate 103, according to some implementations of the present disclosure as shown in FIG. 6A. The narrow recesses 602 will accommodate the press-fit pin assemblies 108. The wide recess 604 will accommodate the connection post 106. In some implementations, the narrow recesses 602 and the wide recess 604 can have respective depths that extend through most, but not all, of the first conductive layer 120.

In addition to the narrow recesses 602 and the wide recess 604, a lower notch 606 can be formed in the second conductive layer 124 and an upper notch 608 can be formed in the first conductive layer 120. In some implementations, the lower notch 606 extends through the entire thickness of the second conductive layer 124. In some implementations, the upper notch 608 extends through the entire thickness of the first conductive layer 120.

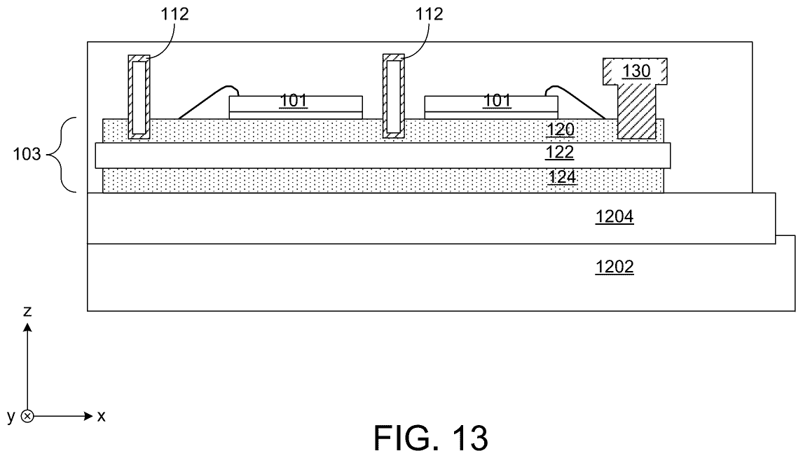

At 504, the method 500 includes inserting external connectors into the narrow recesses 602 and the wide recess 604, according to some implementations of the present disclosure, as shown in FIG. 6B. A first type of external connector, the conductive sheath 112, can be inserted into each of the narrow recesses 602. The conductive sheath 112 shown in FIG. 13 is a tubular type holder, as an example. However, the conductive sheath 112 can take on other forms, such as those shown in FIGS. 3A-3G.

A second type of external connector, the connection post 106, together with the T-shaped power tap 130, can be inserted into the wide recess 604. In some implementations, the external connectors contact the first conductive layer 120 directly without solder, thus forming a substantially homogeneous material interconnection having low electrical resistance, high reliability, and a low level of stray inductance.

At 506, the method 500 includes molding and grinding operations, according to some implementations of the present disclosure, as shown in FIG. 7. First, a molding process can be carried out to encapsulate the power module 100 with the encapsulant 110, e.g., an epoxy molding compound (EMC). In some implementations, the molding process can be, for example, an injection molding process or a transfer molding process. With reference to FIGS. 6A and 6B, the encapsulant 110 fills the upper notch 608, creating a molding extension 708 that secures the encapsulant 110 to the first conductive layer 120. Next, a grinding operation can be carried out, as shown in FIG. 7, by a grinding head 700 moving across the encapsulant 110 e.g., from left to right, to planarize the tops of the conductive sheath 112, the power tap 130, and the encapsulant 110. During the grinding operation, the conductive sheaths 112, e.g., closed conductive sheaths, are cut, creating open conductive sheaths having exposed cavities 712. In some implementations, the grinding head 700 is a circular grinding head that rotates around a vertical axis A-A′ such that a lower surface 710 of the grinding head 700 cuts through the encapsulant 110 along a horizontal path 720, e.g. along a path in the x-direction, indicated by the dotted line in FIG. 7.

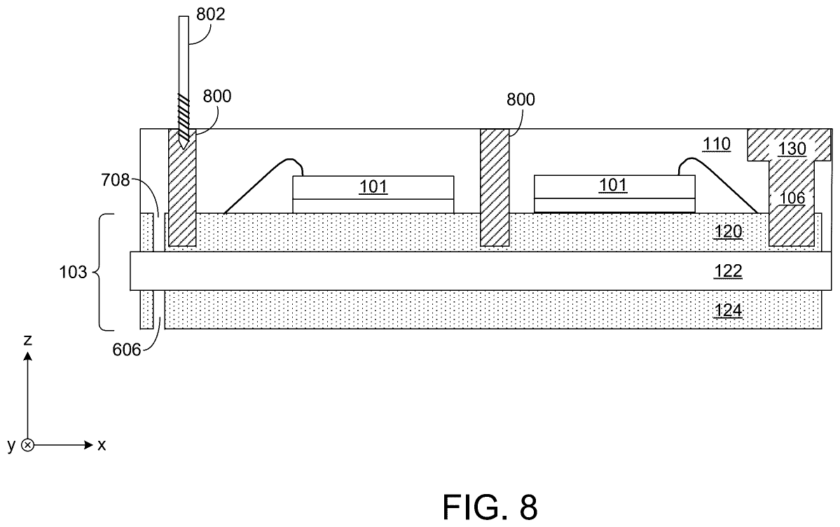

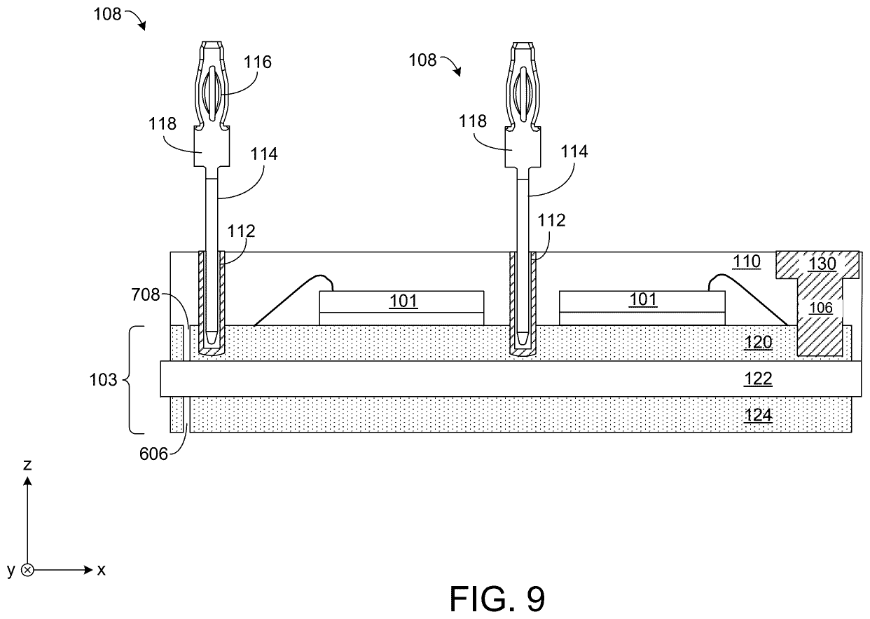

At 508, the method 500 includes inserting pins into the external connectors, according to some implementations of the present disclosure, as shown in FIG. 8 and FIG. 9. First, the external connectors, e.g., the conductive sheaths 112, can be filled with copper to create copper plugs 800, as shown in FIG. 8. Next, precision openings can be formed in the copper plugs 800 using a drill 802. The precision openings created by the drill 802 will be the correct size to accommodate the press-fit pins 114. For example, if the press-fit pin 114 has a diameter of 0.8 mm, the precision opening may be sized at 0.7 mm so that the opening is about 0.1 mm smaller than the pin diameter. Next, the press-fit pin assemblies 108 can be installed by inserting the press-fit pins 114 into the drilled precision openings as shown in FIG. 9. Each press-fit pin assembly 108 includes a press-fit pin 114, flexible metal blades 116, and a flat portion 118. In some implementations, drilling precision openings can be an alternative to the grinding operation.

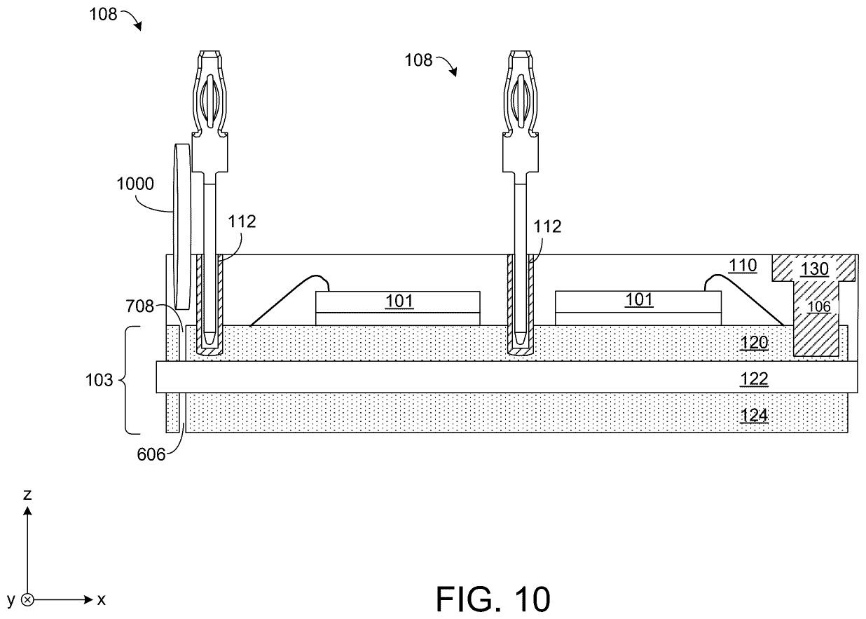

At 510, the method 500 includes a singulation operation, according to some implementations of the present disclosure. The singulation operation separates individual power modules 100 from a common substrate, e.g., the multilayer substrate 103. Although only one power module 100 is explicitly shown in FIG. 10, it is understood that many such power modules 100 can be fabricated on a common substrate and can be separated from one another during the singulation operation at 510. The singulation process is illustrated in FIG. 10 by a blade 1000, e.g., a saw blade, that can be aligned with the lower notch 606 in the second conductive layer 124 and the molding extension 708 in the first conductive layer 120. The blade 1000 is positioned to make a vertical cut through the encapsulant 110 and the multilayer substrate 103 adjacent to the press-fit pin assembly 108. In some implementations, the singulation operation at 510 can precede the pin insertion operation at 508.

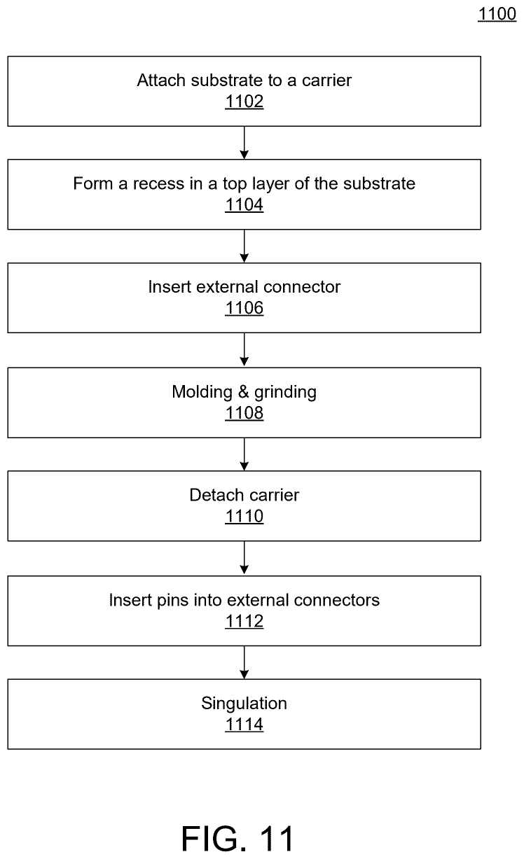

FIG. 11 is a flow chart illustrating a method 1100 for fabricating the power module 100, according to some implementations of the present disclosure. The method 1100 can be considered as an alternative to the method 500. Operations of method 1100 can be performed in a different order, or not performed, depending on specific applications. It is noted that method 1100 may not produce a complete power module 100. Accordingly, it is understood that additional processes can be provided before, during, or after method 1100, and that some of these additional processes may be briefly described herein.

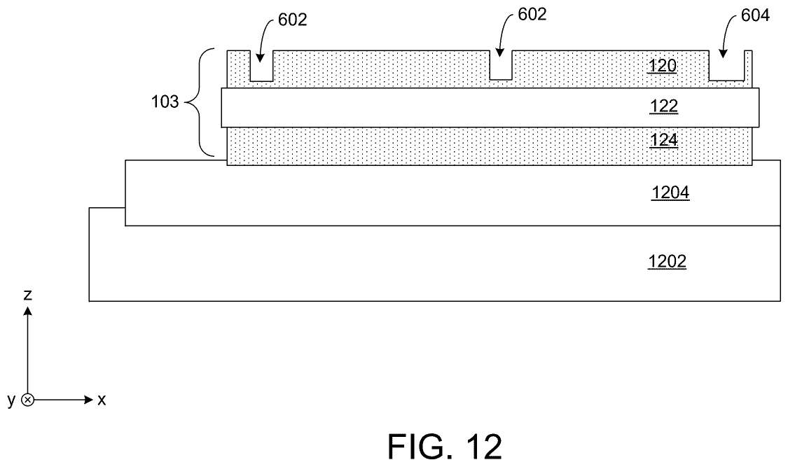

Operations 1102-1114 can be carried out to form the power module 100 according to some implementations as described above, with reference to FIGS. 12-16.

At 1102, the method 1100 includes attaching a substrate, e.g., the multilayer substrate 103, to a carrier 1202, e.g., a carrier jig, according to some implementations of the present disclosure as shown in FIG. 12. In some implementations, attaching the multilayer substrate 103 to the carrier 1202 can use an adhesive layer 1204. In some implementations, the multilayer substrate 103 can have narrow recesses 602 and/or wide recess(es) already formed in the first conductive layer 120.

At 1104, the method 1100 includes forming one or more narrow recesses 602 in a top layer of the substrate, e.g., in the first conductive layer 120 of the multilayer substrate 103, according to some implementations of the present disclosure as shown in FIG. 12. In some implementations, the multilayer substrate 103 can have a narrow recess 602 or multiple narrow recesses 602 already formed in the first conductive layer 120 prior to attaching the carrier 1202.

At 1106, the method 1100 includes inserting external connectors into the narrow recesses 602 and the wide recess 604, according to some implementations of the present disclosure as shown in FIG. 13. In some implementations, the external connectors can include the conductive sheaths 112 for the press-fit pin assemblies 108, and/or the connection post 106 and the power tap 130. The conductive sheath 112 shown in FIG. 13 is a tubular type holder, as an example. However, the conductive sheath 112 can take on other forms, such as those shown in FIGS. 3A-3G.

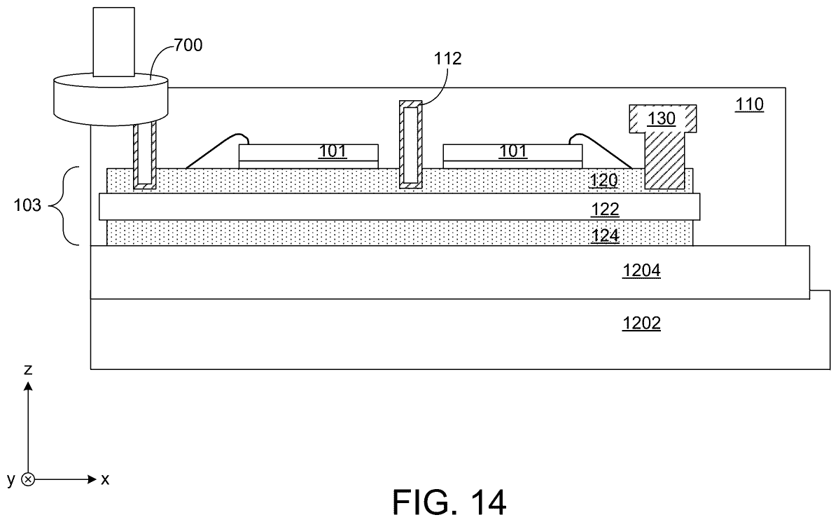

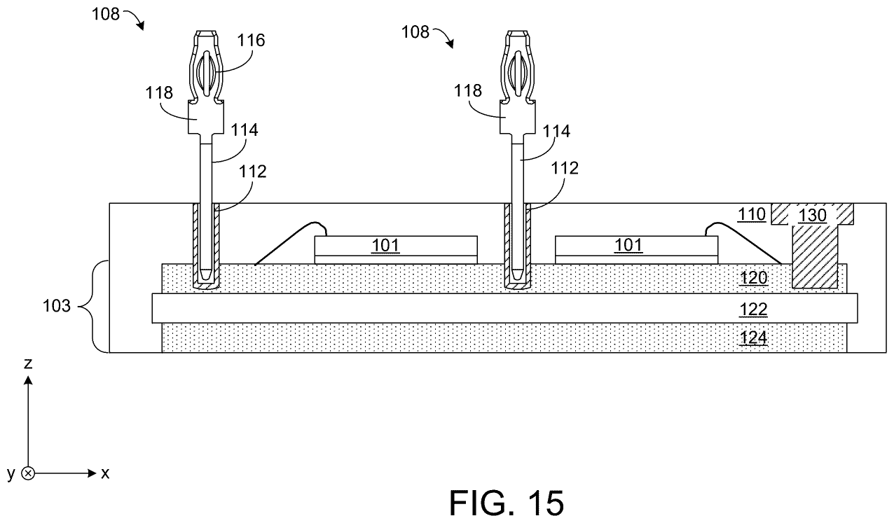

At 1108, the method 1100 includes molding and grinding operations, according to some implementations of the present disclosure, as shown in FIG. 13 and FIG. 14. First, a molding process can be carried out to encapsulate the power module 100 with the encapsulant 110, e.g., an epoxy molding compound (EMC). In some implementations, the molding process can be, for example, an injection molding process or a transfer molding process. As shown in FIGS. 13, 14, 15, and 16, the encapsulant 110 extends down to a top surface of the adhesive layer 1204. Next, a top grinding process can be carried out to open the conductive sheaths 112 and to thin the power tap 130. The top grinding process is depicted in FIG. 14 by the grinding head 700 moving across the encapsulant 110 e.g., from left to right, to planarize the tops of the conductive sheath 112, the power tap 130, and the encapsulant 110.

At 1110, the method 1100 includes detaching the carrier 1202 and the adhesive layer 1204 from the multilayer substrate 103, according to some implementations of the present disclosure as shown in FIG. 15.

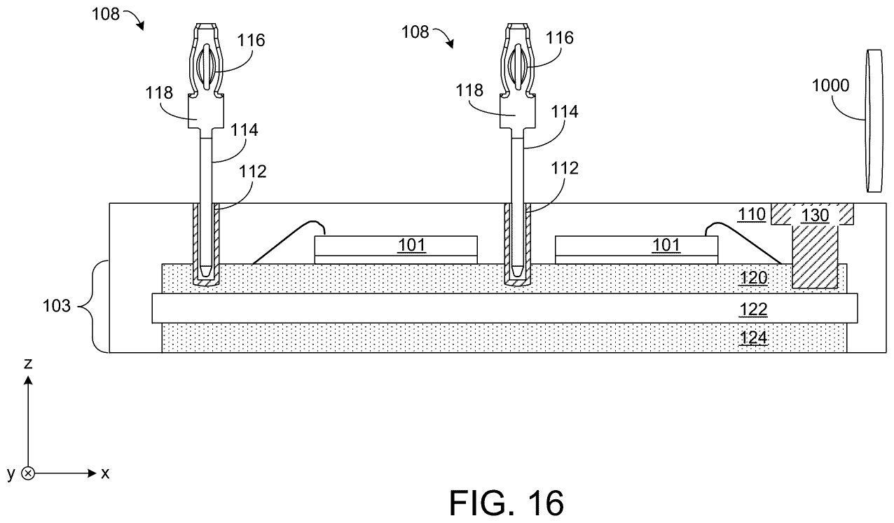

At 1112, the method 1100 includes inserting pins into external connectors, according to some implementations of the present disclosure, with reference to FIGS. 8 and 15. First, the external connectors, e.g., the conductive sheaths 112, having been opened, can be filled with copper to create copper plugs 800, as shown in FIG. 8. Next, precision openings can be formed in the copper plugs 800 using a drill 802. The precision openings created by the drill 802 will be the correct size to accommodate the press-fit pins 114. Next, the press-fit pin assemblies 108 can be installed by inserting the press-fit pins 114 into the drilled precision openings as shown in FIG. 16. Each press-fit pin assembly 108 includes a press-fit pin 114, flexible metal blades 116, and a flat portion 118.

At 1114, the method 1100 includes a singulation operation, according to some implementations of the present disclosure, with reference to FIG. 16. The singulation operation separates individual power modules 100 from a common substrate, e.g., the multilayer substrate 103. Although only one power module 100 is explicitly shown in FIG. 10, it is understood that many such power modules 100 can be fabricated on a common substrate. The singulation process is illustrated by a blade 1000, e.g., a saw blade, that can be aligned with a gap between adjacent sections of the multilayer substrates 103 so as to make a vertical cut through the encapsulant 110 and the multilayer substrate 103 adjacent to each connection post 106. In some implementations, the singulation operation at 1114 can precede the pin insertion operation at 1112.

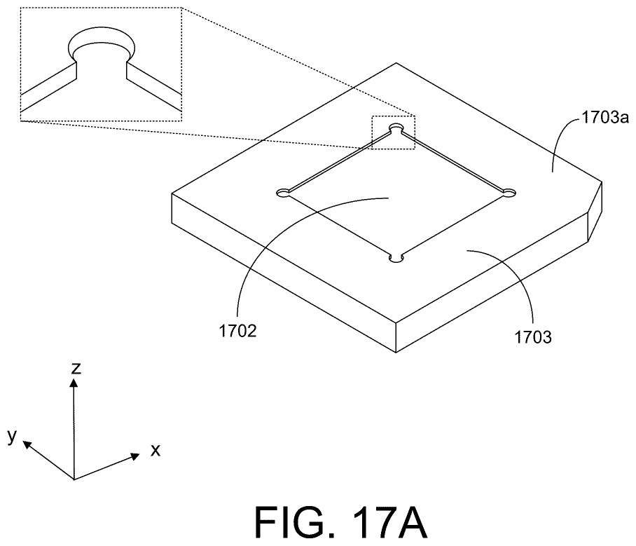

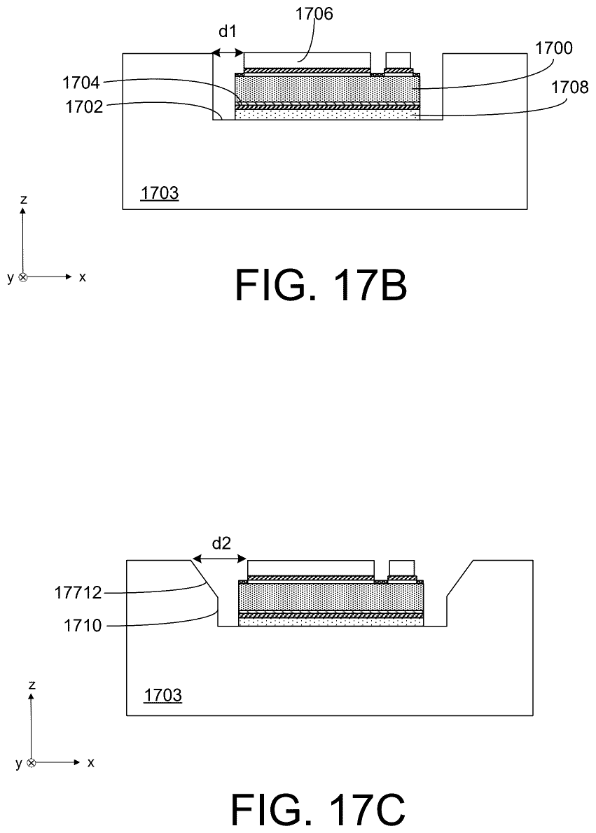

With reference to FIGS. 17A-17C, in some implementations, the semiconductor die 101 can be an embedded die 1700, according to some implementations of the present disclosure. As shown in FIG. 17A, the embedded die 1700 can be set in a trench 1702 formed in a top surface 1703a of a substrate 1703 instead of being mounted on the top surface 1703a. In some implementations, the substrate 1703 can be the first conductive layer 170 of the multilayer substrate 103 shown in, for example, FIG. 1 (or any of the other figures). In some implementations, the substrate 1703 can be a copper lead frame. In some implementations, the trench 1702 can be sized so as to create a gap around the die 1700, separating the die 1700 from the surrounding substrate 1703 by a substantially uniform distance d1. In some implementations, the embedded die 1700 can be fabricated by processing a silicon, silicon carbide (SiC), or gallium nitride (GaN) semiconductor wafer prior to embedding the die in the substrate 1703.

As shown in FIG. 17B, such processing can include, for example, back side copper metallization forming a drain contact 1704 and top side copper metallization forming a source contact 1706 having a thickness of about 10 μm. The metallization process can include one or more metal and/or one or more insulating layers that can function as build-up layers that can result in one or more of the source contact 1706 and the drain contact 1704 being multi-layer structures. In some implementations, the metallization layers can be added after embedding the die 1700 in the substrate. 1703. In some implementations, the embedded die 1700 can be attached to the substrate 1703 using a die attach material 1708 such as solder or sintered silver.

As shown in FIG. 1C, in some implementations, a vertical wall 1710 of the trench 1702 can feature a chamfered edge 1712. The chamfered edge 1712 creates a non-uniform, e.g., graduated, distance d2 between the source contact 1706 and the substrate 1703, wherein the distance d2 is greater than the distance d1 between the die 1700 and the substrate 1703.

The embedded die 1700 can offer improved performance over surface-mounted dies, due to shorter connections, which are therefore faster. Embedded dies can also result in a semiconductor package that is more compact, and by extension, can result in, for example, a miniaturized printed circuit board (PCB).

In some implementations, one or more of the semiconductor dies 101 can be packaged using embedded die packaging technology in which one or more of the semiconductor dies 101 can be embedded in a PCB, as opposed to being mounted on a top surface of the PCB, to gain similar advantages to those of dies embedded in a substrate 1703. When a system-on-chip (SOC), or multiple chips, are embedded in a PCB, a resulting system can be referred to as a system-in-board (SiB).

In some implementations, to further enhance performance, one or more semiconductor die can be embedded in the substrate 1703, and can then also be packaged using embedded die packaging.

In some implementations, one or more of the semiconductor die 101 can include one or more metal and/or one or more insulating layers that can function as build-up layers within the one or more semiconductor die 101.

As described above, at least two different methods can be performed (e.g., carried out) to form the power module 100 with lead frame-less external connectors. One of the methods makes use of a removeable carrier jig to assist in fitting a connection post 106 and one or more press-fit pin assemblies 108 into a top metal layer of a DBM substrate.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes, and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations thereof and/or sub-combinations of the functions, components and/or features of the different implementations described.

1. A power module, comprising:
a substrate including a first conductive layer, a second conductive layer, and an insulating layer disposed between the first conductive layer and the second conductive layer;
a connection post coupled to the first conductive layer;
a conductive sheath coupled to the first conductive layer, the conductive sheath configured to receive an external connector;
a die coupled to the first conductive layer; and
a non-conducting material encapsulating the die, at least a portion of the connection post, and the conductive sheath.

2. The power module of claim 1, further comprising a press-fit pin inserted vertically into the conductive sheath.

3. The power module of claim 2, wherein the connection post, the conductive sheath, and the press-fit pin include copper.

4. The power module of claim 2, wherein the conductive sheath is a hollow metal via.

5. The power module of claim 1, wherein the connection post has a shape of a cylinder, a square pillar, a round pillar, or a hybrid pillar.

6. The power module of claim 1, wherein the connection post and a press-fit pin form external connections to the die.

7. The power module of claim 1, wherein the connection post is formed as a pillar that includes a cylinder coupled to a base.

8. The power module of claim 7, wherein the cylinder and the base have cross-sections of different shapes.

9. The power module of claim 1, further comprising a power tap disposed on the connection post.

10. A method of forming a power module, the method comprising:
adhering a multilayer substrate to a carrier, the multilayer substrate including a first conductive layer, a second conductive layer, and an insulating layer;
disposing an external connector in a first conductive layer of the multilayer substrate;
attaching a die to the first conductive layer;
encapsulating the die and the external connector;
detaching the carrier from the multilayer substrate; and
singulating the multilayer substrate.

11. The method of claim 10, wherein disposing the external connector in the first conductive layer includes forming a recess in the first conductive layer and inserting the external connector into the recess.

12. The method of claim 10, wherein disposing the external connector in the first conductive layer includes disposing a connection post in the first conductive layer.

13. The method of claim 12, further comprising forming a power tap on the connection post.

14. The method of claim 10, wherein disposing the external connector in the first conductive layer includes disposing a conductive sheath in the first conductive layer.

15. The method of claim 14, further comprising inserting a press-fit pin into the conductive sheath to couple the press-fit pin to the first conductive layer.

16. The method of claim 10, wherein encapsulating the die and the external connector includes injection molding and grinding an encapsulant.

17. A package for an embedded semiconductor die, the package comprising:
a multilayer substrate supporting the embedded semiconductor die;
an encapsulant surrounding the embedded semiconductor die; and
a plurality of electrical connections coupling the embedded semiconductor die to the multilayer substrate, the plurality of electrical connections including:
a conductive material coupled to a surface layer of the multilayer substrate;
a connection post embedded in the surface layer; and
a press-fit pin assembly embedded in the surface layer, the press-fit pin assembly including a conductive sheath.

18. The package of claim 17, wherein the multilayer substrate is a direct bond copper substrate including a dielectric layer between two copper layers.

19. The package of claim 17, wherein the press-fit pin assembly includes a press-fit pin, a flat portion, and flexible metal blades.

20. The package of claim 17, wherein the connection post is T-shaped.

21. The package of claim 17, wherein the connection post is a solid metal via.

22. The package of claim 17, wherein the conductive sheath is a hollow metal via.

23. The package of claim 17, wherein the encapsulant includes a non-electrically conducting material.

24. The package of claim 17, wherein the encapsulant includes an organic material.

25. The package of claim 17, wherein the encapsulant includes multiple layers.

26. The package of claim 17, further comprising one or more additional semiconductor dies.

27. The package of claim 17, wherein the embedded semiconductor die includes at least one of silicon, silicon carbide, gallium nitride, or another compound semiconductor material, and combinations thereof.
